(19) United States
(12) Patent Application Publication
(10) Pub. No.: US 2011/0143033 A1
(43) Pub. Date: Jun. 16, 2011

(54) VACUUM PROCESSING APPARATUS AND VACUUM PROCESSING METHOD

(75) Inventors: Eiichi IIJIMA, Chigasaki-shi (JP); Hiroto Ikeda, Chigasaki-shi (JP); Muneto Hakomori, Chigasaki-shi (JP)

(73) Assignee: ULVAC, INC, Chigasaki-shi (JP)

(21) Appl. No.: 13/017,519

(22) Filed: Jan. 31, 2011

Related U.S. Application Data
(63) Continuation of application No. PCT/JP09/63799, filed on Aug. 4, 2009.

(30) Foreign Application Priority Data
Aug. 5, 2008 (JP) 2008-201693

(51) Int. Cl. B05D 3/00; B05C 9/10; B05C 9/14; B05C 11/00; B05D 3/02; C23C 16/40; C23C 16/455; C23C 16/448; C23C 16/46

(52) U.S. Cl. 427/248.1; 118/50; 118/726; 427/294

(57) ABSTRACT

A vacuum processing apparatus has a degassing chamber and does not need a large-sized vacuum evacuation device. In the process of heating and degassing an object to be processed in the degassing chamber, transferring the object to be processed into a processing chamber through a buffer chamber; and performing vacuum processing, the degassing chamber is connected to an vacuum evacuation system having a low evacuation speed and degassing processing is performed in a vacuum atmosphere of 1 to 100 Pa (time 0 to t₂). Next, the object to be processed is moved to the buffer chamber, and the pressure inside the buffer chamber is lowered to near the pressure of the processing chamber (time t₂ to t₃), then the buffer chamber and the processing chamber are connected, and the object to be processed is transferred into the processing chamber. Comparing changes in pressure, the present invention (a group of curves A) has no difference in the processing time as compared to a conventional technology (a group of curves B) where the degassing chamber is put in a high vacuum atmosphere by an vacuum evacuation device having a high evacuation speed.

This application is a continuation of International Application No. PCT/JP2009/63799, filed on Aug. 4, 2009, which claims priority to Japan Patent Application No. 2008-201693, filed on Aug. 5, 2008. The contents of the prior applications are herein incorporated by reference in their entireties.

### BACKGROUND OF THE INVENTION

1. Field of the Invention

The present invention relates to a vacuum processing apparatus that has a degassing chamber, and more particularly to a vacuum processing apparatus that process a substrate in a high vacuum atmosphere after degassing the same.

2. Description of the Background Art

A vacuum processing apparatus for a substrate, which is carried in from air atmosphere, has a degassing chamber in a stage prior to a processing chamber; and the substrate is heated in the degassing chamber to release absorbed gas, and then transferred into the processing chamber to perform vacuum processing (such, as thin film deposition and surface treatment).

In particular, if the vacuum processing apparatus is an MgO deposition apparatus for forming an MgO thin film on the surface of the substrate, the substrate is mounted on a carrier in air before placed into the carry-in chamber, so that a large amount of gas is thus absorbed in the carrier. Accordingly, in the process of moving the substrate from the carry-in chamber into the processing chamber, the substrate and the carrier are transferred into the degassing chamber, to be heated along with vacuum evacuation as long as possible, in order to reduce the amount of absorbed gas which is released from the substrate and the carrier, until the degassing chamber reaches a high vacuum atmosphere inside, and then the substrate and the carrier are moved to the processing chamber.

For that purpose, vacuum pumps having an evacuation capability as large volume as possible are connected to the carry-in chamber, the degassing chamber, a buffer chamber, or the like as well as the processing chamber so as to carry out evacuation up to a high vacuum atmosphere.

However, for high vacuum evacuation of the carry-in chamber, a high vacuum evacuation pump (turbomolecular pump or cryopump) needs to be connected to the carry-in chamber through a 20-inch or greater valve, and when processing substrates at a takt time of 80 seconds, the opening-closing frequency is 27000 times or higher a month, which requires the necessity for an overhaul of approximately every three months; subsequently, valve overhauling and breakdowns become a major cause of apparatus downtime.

Also, a plurality of degassing chambers have been connected in series; and a high vacuum evacuation pump (a combination of a cold trap and a turbomolecular pump, or a cryopump) has been connected to each of the degassing chambers (a back pump is further connected to the high vacuum evacuation pump).

The vacuum evacuation systems are increasing in size due to such reasons as the increasing sizes of the substrates to handle and a demand for contamination reduction, in particular.

As a result, MgO deposition apparatuses become expensive and costly to run, and require a wide installation space and facilities, and solutions thereof have been desired.
See, [Non-Patent Document 1] Dictionary of flat panel display technology, Kogyo Chosakai Publishing, Inc., Dec. 25, 2001, 1st edition, p. 269, pp. 683-684, pp. 688-689, and pp. 737-738.
See, [Non-Patent Document 2] Shinkuhandbook [Vacuum handbook], new edition, Ohmsha, Ltd., Jul. 1, 2002, p. 5 (articles 1 and 2, vacuum terms).

### SUMMARY OF THE INVENTION

The present invention provides a vacuum processing apparatus that can perform processing in a high vacuum atmosphere at low cost without requiring a large-sized vacuum pump.

The principle of operation of the present invention will be described.

In a high vacuum atmosphere, the pressure P (Pa), the amount Q of released gas (Pa·m³/sec), and the effective evacuation speed S (m³/sec) have the relationship P=Q/S. Assuming that the amount Q of released gas is the amount of the absorbed gas released from a carrier and the substrate, the value of the amount Q of released gas may be regarded as a function of time alone, if the carrier and the substrate are heated to a constant temperature for degassing in the vacuum atmosphere. In other words, the amount Q of released gas during thermal degassing is independent of the pressure of the ambient vacuum atmosphere during the thermal degassing.

In other words, while the processing chamber intended for processing needs to be connected to an vacuum evacuation device that can produce a high vacuum atmosphere, the degassing chamber for thermal degassing may be connected to a vacuum evacuation device that has an ultimate pressure lower than that of the vacuum evacuation device connected to the processing chamber, so that the thermal degassing can be performed at a pressure higher than heretofore.

The present invention has been created in view of the foregoing findings, such that an embodiment of the present invention is directed to a vacuum processing apparatus having a degassing chamber that has a substrate heating mechanism and a processing chamber in which vacuum processing to a substrate is performed, the degassing chamber and the processing chamber being put in vacuum atmosphere, and an object to be processed, that has been heated and degassing processed inside the degassing chamber, being transferred into the processing chamber and vacuum processed inside the processing chamber, wherein the evacuation speed of a degassing chamber vacuum evacuation device connected to the degassing chamber is set to be lower than the evacuation speed of a processing chamber vacuum evacuation device connected to the processing chamber.

The present embodiment may also be directed to the vacuum processing apparatus wherein the degassing chamber vacuum evacuation device uses a vacuum pump that has an ultimate pressure which is higher than the ultimate pressure of the processing chamber vacuum evacuation device.

The present embodiment may also be directed to the vacuum processing apparatus wherein an MgO deposition source is arranged in the processing chamber; and MgO vapor of the MgO evaporation source is emitted to form an MgO thin film on a surface of the object to be processed.

The present embodiment may also be directed to the vacuum processing apparatus which includes a plurality of the degassing chambers, the degassing chambers being connected in series, wherein, after the object to be processed is degassing processed in each of the degassing chambers, the object is then moved to the processing chamber.

The present embodiment may also be directed to the vacuum processing apparatus, wherein the degassing chamber vacuum evacuation device has an evacuation speed that brings the pressure inside the degassing chamber to a pressure atmosphere of higher than or equal to 1 Pa and lower than or equal to 100 Pa, and wherein the processing chamber vacuum evacuation device has an evacuation speed that brings the pressure in the processing chamber to below 1 Pa.

An embodiment of the present invention may be directed to a vacuum processing apparatus having a degassing chamber that has a substrate heating mechanism, a buffer chamber that is connected to the degassing chamber, and a processing chamber that is connected to the buffer chamber, the degassing chamber, the buffer chamber, and the processing chamber being put in a vacuum atmosphere, an object to be processed (which has been heated and gone through degassing processed inside the degassing chamber) being transferred into the processing chamber through the buffer chamber and vacuum processed inside the processing chamber, wherein the evacuation speed of a degassing chamber vacuum evacuation device connected to the degassing chamber is set to be lower than the evacuation speed of a buffer chamber vacuum evacuation device connected to the buffer chamber.

The present embodiment may also be directed to the vacuum processing apparatus wherein the evacuation speed of the degassing chamber vacuum evacuation device is set to be lower than the evacuation speed of a processing chamber vacuum evacuation device connected to the processing chamber.

The present embodiment may also be directed to the vacuum processing apparatus wherein the degassing chamber vacuum evacuation device uses a vacuum pump that has an ultimate pressure that is higher than the ultimate pressure of the buffer chamber vacuum evacuation device.

The present embodiment may also be directed to the vacuum processing apparatus wherein an MgO deposition source is arranged in the processing chamber; and MgO vapor of the MgO deposition source is emitted to form an MgO thin film on a surface of the object to be processed.

The present embodiment may also be directed to the vacuum processing apparatus which includes a plurality of the degassing chambers, the degassing chambers being connected in series, wherein, after the object to be processed has gone through degassing processed in each of the degassing chambers, the object is then moved to the buffer chamber.

The present embodiment may also be directed to the vacuum processing apparatus, wherein the degassing chamber vacuum evacuation device has an evacuation speed that brings the pressure in the degassing chamber to a pressure atmosphere of higher than or equal to 1 Pa and lower than or equal to 100 Pa, and wherein the buffer chamber vacuum evacuation device has an evacuation speed that brings pressure inside the buffer chamber to below 1 Pa.

An embodiment of the present invention may be directed to a vacuum processing method in which an object to be processed is mounted onto a carrier to form a transfer unit, the transfer unit being carried from air atmosphere into a vacuum atmosphere, and after heating the transfer unit being heated and degassing processed inside a degassing chamber, being transferred into a buffer chamber; and after the pressure in the buffer chamber is lowered, the buffer chamber is then connected to a processing chamber, the transfer unit being transferred into the processing chamber, and the object to be processed in the transfer unit being vacuum processed. Pressure in the degassing chamber is brought into a pressure atmosphere of higher than or equal to 1 Pa and lower than or equal to 100 Pa; and pressure in the processing chamber is brought to below 1 Pa.

The present embodiment may be directed to the vacuum processing method in which MgO vapor is produced in the processing chamber to form an MgO thin film on a surface of the object to be processed.

### EFFECT OF THE INVENTION

The degassing atmosphere need not be a high vacuum, which makes the vacuum evacuation system lower in cost and the apparatus installation space smaller.

The carry-in chamber need not be in a high vacuum atmosphere, which makes vacuum evacuation system of the carry-in chamber need not be provided with a large-sized valve.

From the graph of FIG. 4, it can be seen that as long as, in a buffer chamber prior to the processing chamber, vacuum evacuation up to a pressure that allows connection to the processing chamber is performed, the pressure of the carry-in chamber when evacuated to vacuum and the pressure of the degassing chamber when degassing may be higher than approximately three times heretofore.

Consequently, the present invention allowed a significant reduction of the vacuum evacuation systems with an approximately 5% to 10% reduction in the cost of the device. The facility power, the amount of power for device operation, and cooling water were successfully reduced by approximately 5%. The installation space was successfully reduced by approximately 3%. In addition, by omitting unnecessary vacuum evacuation devices, the reliability of the entire apparatus is improved, and the periodic maintenance cost is reduced as well.

### BRIEF DESCRIPTION OF THE DRAWINGS

FIG. 1 is a schematic diagram illustrating an example of a vacuum processing apparatus to be used in an embodiment of the present invention.

FIG. 2 is a diagram for explaining a transfer unit.

FIG. 3 is a schematic diagram for explaining another example of the present invention.

FIG. 4 is a graph showing time variations in pressure of ambient atmosphere around the transfer unit.

FIG. 5(a) is a single substrate vacuum processing apparatus to be used in an example of the present invention; and FIG. 5(b) is a single substrate vacuum processing apparatus to be used in a conventional technology.

### DETAILED DESCRIPTION OF THE PREFERRED EMBODIMENTS

### Best Mode for Carrying Out the Invention

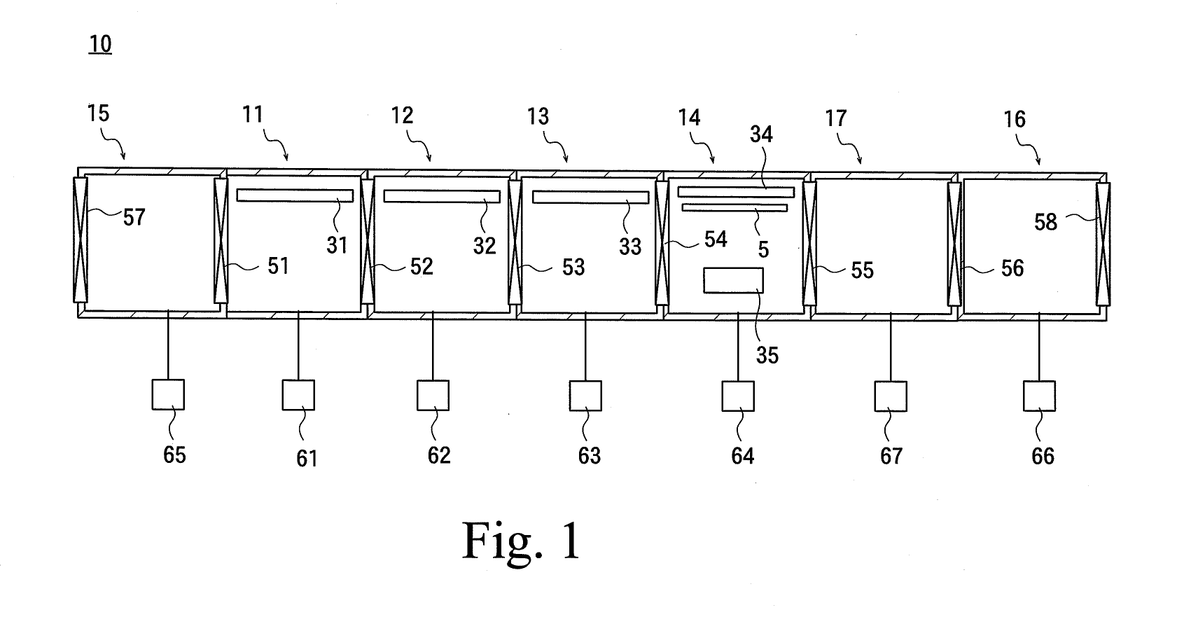

Referring to FIG. 1, the reference numeral 10 represents the vacuum processing apparatus to be used in one example of the present invention.

The vacuum processing apparatus 10 includes a carry-in chamber 15, a first degassing chamber 11, a second degassing chamber 12, a buffer chamber 13, a processing chamber 14, a cooling chamber 17, and a take-out chamber 16. The chambers 15, 11 to 14, 17, and 16 are arranged in this order, and are connected in series through gate valves 51 to 56.

First and second degassing chamber vacuum evacuation devices 61 and 62 are connected to the first and second degassing chambers 11 and 12, respectively; a buffer chamber vacuum evacuation device 63 is connected to the buffer chamber 13; and a processing chamber vacuum evacuation device 64 is connected to the processing chamber 14. A cooling chamber vacuum evacuation device 67 is connected to the cooling chamber 17.

In order to start a vacuum processing operation, the gate valves 51 to 56 are closed and the vacuum evacuation devices 61 to 64 and 67 are activated to evacuate to vacuum the inside of the first and second degassing chambers 11 and 12, the buffer chamber 13, the processing chamber 14, and the cooling chamber 17 in advance.

After the operation has started, the vacuum evacuation devices 61 to 64 and 67 are respectively kept in operation to continue evacuating the first and second degassing chambers 11 and 12, the buffer chamber 13, the processing chamber 14, and the cooling chamber 17.

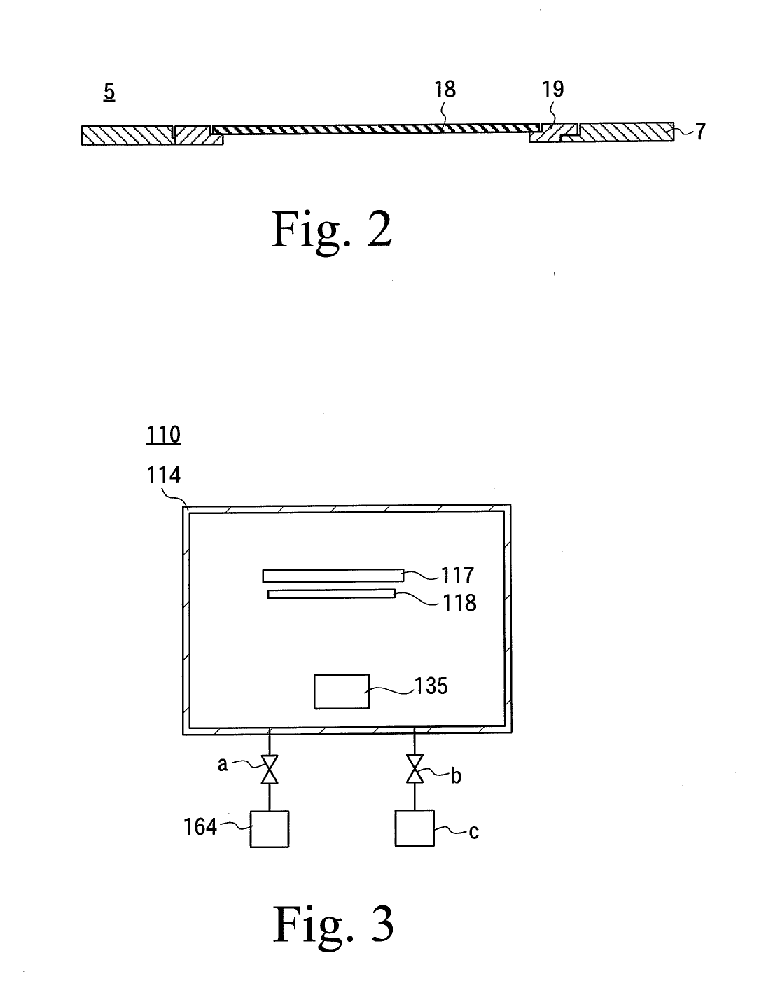

As shown in FIG. 2, an object to be processed 18 (such as, a glass substrate) is set on a carrier 7 by a frame 19, thereby constituting a transfer unit 5; and a door 57 between the carry-in chamber 15 and air atmosphere is opened so as to carry the transfer unit into the carry-in chamber 15.

When a predetermined number of transfer units 5 are carried into the carry-in chamber 15, the door 57 is closed and the carry-in chamber 15 is evacuated to vacuum by the carry-in chamber vacuum evacuation device 65.

When the interior of the carry-in chamber 15 reaches a predetermined pressure of approximately 100 Pa, the gate valve 51 is opened to move one of the transfer units 5 from the carry-in chamber 15 into the first degassing chamber 11.

First and second heating mechanisms 31 and 32 are arranged in the first and second degassing chambers 11 and 12, respectively, which keeps the first heating mechanism 31 generate heat by applying electric current in advance, and then with the transfer unit 5 made to be opposed to the first heating mechanism 31 and the gate valve 51 to the carry-in chamber 15 closed to heat the transfer unit 5, absorbed gas that has been absorbed in the transfer unit 5 is released out from the transfer unit 5 with raised temperature into the interior of the first degassing chamber 11.

The absorbed gas released from the transfer unit 5 is evacuated to vacuum by the first vacuum evacuation device 61. As the interior of the first degassing chamber 11 continues being evacuated to vacuum by the first vacuum evacuation device 61 and the amount Q₁ of the released gas decreases with the passage of time during the degassing processing, the internal pressure of the first degassing chamber 11 also decreases.

Because the first vacuum evacuation device 61 has an effective evacuation speed S₁ of such a degree that the degassing processing for a first degassing processing time which has been preset in advance can bring the pressure P₁ inside the first degassing chamber 11 into the range of 1 to 100 Pa, after an elapse of the first degassing processing time, the gate valve 52 is opened to move the transfer unit 5 from the first degassing chamber 11 to the second degassing chamber 12.

The transfer unit 5 is opposed to the second heating mechanism 32. With the gate valve 52 closed, the inside of the second degassing chamber 12 is evacuated to vacuum by the second vacuum evacuation device 62 while the transfer unit 5 is heated.

In this embodiment, the transfer unit 5 is degassed in the second degassing chamber 12 for a second degassing processing time that has been preset in advance.

Like the effective evacuation speed S₁ of the first vacuum evacuation device 61, the second vacuum evacuation device 62 has an effective evacuation speed S₂ of such a degree that the degassing processing for the second degassing processing time that has been preset in advance can bring the pressure P₂ inside the second degassing chamber 12 into the range of 1 to 100 Pa.

In this embodiment, the effective evacuation speed S₂ of the second vacuum evacuation device 62 is the same as the effective evacuation speed S₁ of the first vacuum evacuation device 61. However, because the amount Q₂ of the absorbed gas released from the transfer unit 5 inside the second degassing chamber 12 is smaller than the amount Q₁ of the gas released in the first degassing chamber 11, while the degassing processing progresses in the second degassing chamber 12, an internal pressure P₂ of the second degassing chamber 12 becomes lower than an internal pressure P₁ of the first degassing chamber 11.

After an elapse of the second degassing processing time that has been set, the gate valve 53 is opened and the transfer unit 5 is moved into the buffer chamber 13.

The buffer chamber vacuum evacuation device 63 is a high vacuum evacuation pump and has an evacuation speed S₃ higher than the evacuation speeds S₁ and S₂ of the first and second vacuum evacuation devices 61 and 62, so that, with the gate valve 53 closed, the buffer chamber 13 is evacuated to vacuum by the buffer chamber vacuum evacuation device 63, the pressure in the buffer chamber 13 rapidly decreases.

In this embodiment, the buffer chamber 13 is provided with a buffer chamber heating mechanism 33 to which the transfer unit 5 is made to oppose, and raise the temperature to nearly equal to the ones inside the first and second degassing chambers 11 and 12, in order to lower the pressure in the buffer chamber 13 while degassing.

Since the processing chamber 14 has been evacuated to vacuum up to a high vacuum atmosphere in advance, after the internal pressure of the buffer chamber 13 is lowered to nearly equal to the internal pressure of the processing chamber 14, the gate valve 54 is opened in order to move the transfer unit 5 into the processing chamber 14, and then the gate valve 54 is closed.

The processing chamber vacuum evacuation device 64 is a high vacuum evacuation pump and has an evacuation speed S₄ higher than or equal to the evacuation speed S₃ of the buffer chamber vacuum evacuation device 63. The interior of the processing chamber 14 can be reduced to a pressure which is lower than the pressure of the buffer chamber 13.

An MgO evaporation source 35 is placed inside the processing chamber 14. The transfer unit 5 is arranged with the surface of the object to be processed 18 directed toward the MgO evaporation source 35, so that when MgO vapor is released from the MgO evaporation source 35, the MgO vapor reaches the surface of the object to be processed 18 to grow an MgO thin film.

After a predetermined thickness of MgO thin film is formed, the gate valve 55 is opened and the transfer unit 5 is moved to the cooling chamber 17 for cooling down, after the cooling the transfer unit 5 is moved to the take-out chamber 16.

By sequentially transferring unprocessed transfer units into the processing chamber 14, the vacuum processing (the formation of the MgO thin film) can be performed on the plurality of objects to be processed in succession.

After a predetermined number of vacuum-processed transfer units 5 are placed inside the take-out chamber 16, a door 58 leading into the air is opened with the gate valve 56 closed in order to take the transfer units 5 out into the air.

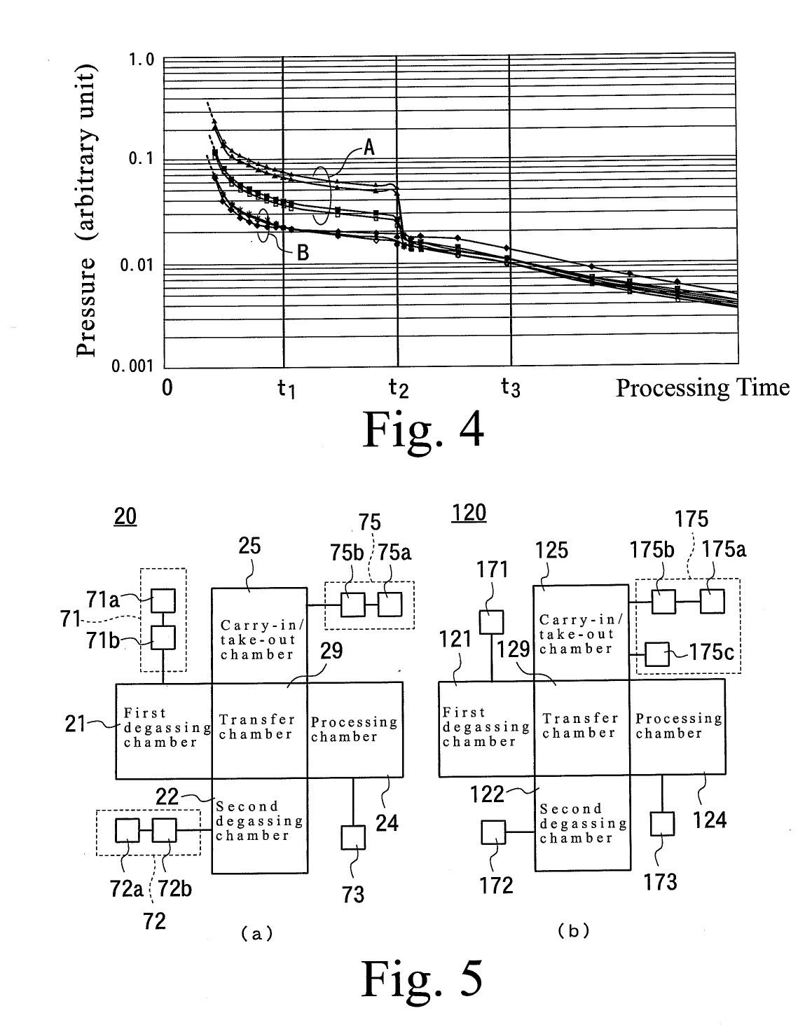

FIG. 4 is a graph showing the relationship between elapsed time inside the vacuum processing apparatus 10 and pressure of the ambient atmosphere around a transfer unit 5, in which the horizontal axis shows the elapsed time, and the vertical axis shows the pressure (in an arbitrary unit).

The origin point 0 of the horizontal axis represents the time when the degassing processing had started in the first degassing chamber 11; the symbol t₁ represents the time when the transfer unit 5 was moved from the first degassing chamber 11 to the second degassing chamber 12; the symbol t₂ represents the time when moved from the second degassing chamber 12 to the buffer chamber 13; and the symbol t₃ represents the time when moved from the buffer chamber 13 to the processing chamber 14.

The group of curves represented by the symbol A shows changes in pressure when the present invention is applied. The group of curves represented by the symbol B shows changes in pressure in the conventional technology.

If the transfer unit 5 is heated to the same temperature when degassing, the speed of release of the absorbed gas depends on the degassing time. In the case of the same release speed, the pressure of the vacuum atmosphere depends on the effective evacuation speed of the evacuation vacuum system, the pressure in the buffer chamber 13 is therefore the same both in the present invention where the degassing is performed at a high pressure and in the conventional technology where the degassing is performed in a high vacuum atmosphere.

While the vacuum processing apparatus 10 described above is provided individually with the separate vacuum evacuation devices 61 to 67, it is possible, for example, to share one or a plurality of evacuation devices. For example, the vacuum evacuation devices 65 and 66 of the carry-in chamber 15 and the take-out chamber 16 may be shared.

Up to this point, a description has been given on the embodiment where the pressure in the degassing chamber is brought into a pressure atmosphere of higher than or equal to 1 Pa and lower than or equal to 100 Pa, and the pressure in the buffer chamber is brought to below 1 Pa; nevertheless, the present invention may also be applied to a vacuum processing apparatus in which the pressure in the degassing chamber is brought into a pressure atmosphere of higher than or equal to 0.1 Pa and lower than or equal to 100 Pa, and the pressure in the buffer chamber is brought to below 0.1 Pa.

Next, another example of the method of the present invention will be described.

The reference numeral 110 in FIG. 3 is a vacuum processing apparatus that can be used for the method of the present invention, which has a vacuum chamber 114.

A substrate heating mechanism 117 is arranged in the vacuum chamber 114; and an object to be processed 118 is disposed opposite to the substrate heating mechanism 117.

Vacuum evacuation devices c and 164 are connected to the vacuum chamber 114 through valves. The vacuum evacuation device with the symbol c is intended for roughing; and the vacuum evacuation device with the numeral 164 is intended for high vacuum evacuation. While the roughing vacuum evacuation device c evacuates the vacuum chamber 114, the object to be processed 118 is heated by the substrate heating mechanism 117, thereby the gas absorbed in the object to be processed 118 is released and degassing processing is performed. The absorbed gas released is discharged into the air atmosphere by the roughing vacuum evacuation device c.

The high vacuum evacuation device 164 includes a cryopump. However, with valve a between the high vacuum evacuation device 164 and the vacuum chamber 114 closed during degassing processing, the degassing processing is performed by the roughing vacuum evacuation device c. Since the cryopump is not connected to the internal atmosphere of the vacuum chamber 114, the cryopump will not absorb gas.

During the degassing without using the cryopump, the interior of the vacuum chamber 114 is maintained at pressures of higher than or equal to 1 Pa and lower than or equal to 100 Pa. After the degassing processing on the object to be processed 118 is performed in such pressure range for a predetermined time, the cryopump is connected to the internal atmosphere of the vacuum chamber 114, to have the vacuum chamber 114 evacuated to vacuum at a high effective evacuation speed S₅ of the cryopump; thereby, the pressure of the interior of the vacuum chamber 114 is lowered to a pressure P₅ (=Q₅/S₅) that is determined by the amount Q₅ of the released gas after the degassing and the effective evacuation speed S₅ of the cryopump.

An MgO evaporation source 135 is placed in the lower part of the vacuum chamber 114, and after the low pressure P₅ is reached, MgO vapor is emitted from the MgO evaporation source 135 to form an MgO thin film of high quality on the surface of the object to be processed 118.

Since the released gas during the degassing is not absorbed in the cryopump, the regeneration intervals of the cryopump can be lengthened without an increase in the processing time as compared to the conventional technology where the cryopump is used to create a high vacuum even during the degassing processing.

### EMBODIMENT

Specific vacuum pumps for use in the vacuum processing apparatus 10 of the foregoing embodiment is as follows.

The following table 1 shows the composition of the vacuum evacuation devices 61 to 63 and 65 of the vacuum processing apparatus 10 in FIG. 1, the evacuation speeds of the vacuum evacuation devices 61 to 63 and 65, and the pressures in the vacuum chambers when moving the transfer unit 5 to the subsequent vacuum chambers.

TABLE 1
Evacuation systems in the vacuum processing apparatus of the present application

| | Carry-in | | | |
|---|---|---|---|---|
| | chamber | First vacuum | Second vacuum | Buffer chamber |
| | vacuum evacuation | evacuation | evacuation | vacuum evacuation |
| | device 65 | device 61 | device 62 | device 63 |
| Composition | Dry pump | Turbomolecular | Turbomolecular | Turbomolecular |
| | Mechanical | pump | pump | pump |
| | booster pump | | | Cold trap |
| Total | 0.5 | 1.0 | 1.0 | 80 |
| evacuation | | | | |
| speed | | | | |
| (m³/sec) | | | | |
| Pressure (Pa)*¹ | In the range of | In the range of | In the range of | In the range of |
| | 10-10² Pa | 1-10 Pa | 1-10 Pa | 10⁻³ Pa |

*¹Pressure (Pa) when moving the transfer unit to the subsequent vacuum chamber

The chambers 11 to 14, 16, and 17 other than the carry-in chamber 15 have been evacuated to vacuum in advance. The pressure of the processing chamber 14 when performing vacuum processing on the object to be processed 18 is in the 10⁻² Pa range.

The carry-in chamber vacuum evacuation device 65 is an evacuation unit that is composed of a dry pump and a mechanical booster pump and has a total evacuation speed S₁ of 0.5 m³/sec.

The carry-in chamber vacuum evacuation device 65 was activated to evacuate to vacuum the carry-in chamber 15, into which transfer units 5 had been carried, from air pressure to a pressure in the range of 10 to 10² Pa, at which the carry-in chamber 15 was connected to the first degassing chamber 11 to have a transfer unit 5 moved to the first degassing chamber 11.

The first vacuum evacuation device 61 and the second vacuum evacuation device 62 are vacuum evacuation systems, having respective pumping speeds S₂ and S₃ of approximately 1.0 m³/sec that use a turbomolecular pump (and a back pressure pump) of a wide range type for medium and high vacuum evacuation; and while the inside of the first degassing chamber 11 was evacuated to vacuum by the first vacuum evacuation device 61, the transfer unit 5 was heated to release the absorbed gas and perform degassing for a predetermined time; and when the first degassing chamber 11 was evacuated to vacuum down to a pressure in the range of 1 to 10 Pa, the first degassing chamber 11 was connected to the second degassing chamber 12 and the transfer unit 5 was moved to the second degassing chamber 12.

The second degassing chamber 12 was evacuated to vacuum by the second vacuum evacuation device 62, and while maintained at pressures in the range of 1 to 10 Pa, the transfer unit 5 was heated to release the absorbed gas to perform degassing for a predetermined time, after which, with the pressure in the range of 1 to 10 Pa, the second degassing chamber 12 was connected to the buffer chamber 13 and the transfer unit 5 was moved to the buffer chamber 13.

The buffer chamber evacuation device 63 is a high vacuum evacuation system, with a total evacuation speed S₃ of approximately 80 m³/sec, using a turbomolecular pump and a cold trap (and a back pressure pump). While the inside of the buffer chamber 13 was evacuated to vacuum by the buffer chamber high vacuum evacuation device 63, the transfer unit 5 was heated to release the absorbed gas and perform degassing for a predetermined time. After the pressure of the buffer chamber 13 was lowered to the order of 10⁻³ Pa, the buffer chamber 13 was connected to the processing chamber 14 and the transfer unit 5 was moved into the processing chamber 14. When a process gas is introduced into the processing chamber for the process, the pressure of the buffer chamber may be lowered before the buffer chamber is supplied with the processing gas and then connected to the processing chamber.

The processing chamber vacuum evacuation device 64 uses the same vacuum pump as that of the buffer chamber vacuum evacuation device 63, so that an MgO thin film can be deposited in a high vacuum evacuated state.

A description will now be given as to a procedure when using a vacuum processing apparatus of a comparative example, which has the same configuration as that of the foregoing embodiment, except the vacuum evacuation devices.

As in the foregoing embodiment, degassing is performed by heating the transfer unit 5, which is heated in the first and second degassing chambers 11 and 12 and the buffer chamber 13. The following table 2 shows the composition of the vacuum evacuation devices connected to the respective chambers 11 to 13 and 15, and the pressures when moving to the subsequent vacuum chambers.

TABLE 2
Evacuation systems in the vacuum processing apparatus of comparative example

| | Carry-in | | | | |
|---|---|---|---|---|---|
| | chamber | | First vacuum | Second vacuum | Buffer chamber |
| | vacuum evacuation | | evacuation | evacuation | vacuum evacuation |
| | device 65 | | device 61 | device 62 | device 63 |
| Composition | Dry pump | Turbomolecular | Turbomolecular | Turbomolecular | Turbomolecular |
| | Mechanical | pump | pump | pump | pump |
| | booster pump | | Cold trap | Cold trap | Cold trap |
| Total | 4.5 | 6 | 80 | 80 | 80 |
| evacuation | | | | | |
| speed | | | | | |
| (m³/sec) | | | | | |
| Pressure (Pa)*¹ | In the range of | In the range of | In the range of | In the range of | In the range of |
| | 10 Pa | 10⁻¹ Pa | 10⁻² Pa | 10⁻² Pa | 10⁻³ Pa |

*¹Pressure (Pa) when moving the transfer unit to the subsequent vacuum chamber

In the vacuum processing apparatus of the comparative example, the carry-in chamber 15 is connected to an evacuation unit that is composed of a dry pump and a mechanical booster pump with a total evacuation speed of 4.5 m³/sec, and also to a turbomolecular pump (and a back pressure pump) with a evacuation speed of 6.0 m³/sec; the carry-in chamber 15 with transfer units 5 carried therein was initially evacuated to vacuum by means of the evacuation unit, whereby the pressure of the inside of the carry-in chamber 15 was lowered from air pressure to 10 Pa; then, the evacuation operation was switched to the turbomolecular pump, in order to have the carry-in chamber 15 evacuated to vacuum by the turbomolecular pump to lower the pressure of the inside of the carry-in chamber 15 from 10 Pa to 10⁻¹ Pa, at which pressure a transfer unit 5 was moved to the first degassing chamber 11.

The first and second degassing chambers 11 and 12 are connected to respective high vacuum evacuation systems that are composed of a turbomolecular pump and a cold trap (and a back pressure pump) with a total evacuation speed of approximately 80 m³/sec. In the first degassing chamber 11, while vacuum evacuation was performed by its high vacuum evacuation system, the transfer unit 5 was heated and degassed, until the pressure of the inside of the first degassing chamber 11 was reduced to within the range of 10⁻² Pa, at which pressure the first and second degassing chambers 11 and 12 were connected to move the transfer unit 5 into the second degassing chamber 12. The second degassing chamber 12 was also evacuated to vacuum by its high vacuum evacuation system, and while heating and degassing were performed with the pressure maintained in the range of 10⁻² Pa, the second degassing chamber 12 was connected to the buffer chamber 13 at a pressure in the range of 10⁻² Pa.

The buffer chamber 13 is connected to the same high vacuum evacuation system as those of the first and second degassing chambers 11 and 12 (a high vacuum evacuation system using a turbomolecular pump and a cold trap (and a back pressure pump) with a total evacuation speed of approximately 80 m³/sec); and while vacuum evacuation was performed by the high vacuum evacuation system, heating and degassing were performed, and the buffer chamber 13 was connected to the processing chamber 14 at a lowered pressure in the range of 10⁻³ Pa, and the transfer unit 5 was moved.

As described above, when performing vacuum evacuation from air pressure, and heating and degassing the transfer unit 5 and then transferring the transfer unit 5 into the inside of the processing chamber which is in a high vacuum state, both the vacuum processing apparatus of an embodiment of the present invention and the vacuum processing apparatus of the comparative example were able to reduce the pressure from the air pressure to within the range of 10⁻³ Pa within the same time period.

As compared to the comparative example, the vacuum pumps in the first and second vacuum evacuation systems 61 and 62 of the present invention have operating pressure ranges higher than those of the vacuum pumps of the buffer chamber vacuum evacuation device 63 and the processing chamber vacuum evacuation device 64. Assuming that the lowest pressure value in an operating pressure range is the ultimate pressure, the first and second vacuum evacuation systems 61 and 62 have ultimate pressures higher than those of the buffer chamber vacuum evacuation device 63 and the processing chamber vacuum evacuation device 64.

Consequently, according to the present invention, the carry-in chamber 15 need not be connected to a turbomolecular pump, and the first and second degassing chambers 11 and 12 can dispense with a cold trap, which reduces the device costs and makes facilitates maintenance easier.

In this embodiment, the first and second degassing chambers 11 and 12 are evacuated to vacuum by the first and second degassing chamber vacuum evacuation devices 61 and 62 which are composed of a turbomolecular pump. However, a dry pump and a Roots blower pump (mechanical booster pump) may be used for evacuation instead of the turbomolecular pump. Moreover, the present invention is not limited to a vacuum deposition apparatus of an in-line type, but may be applied to a single substrate apparatus, a load lock apparatus, and a hatch-type apparatus.

FIG. 5(a) shows such an embodiment of the present invention, where a vacuum processing apparatus 20 has a transfer chamber 29, with a substrate transfer robot disposed therein, which is connected with a carry-in/take-out chamber 25 for carrying a transfer unit 5 in and taking the same out, first and second degassing chambers 21 and 22 with respective heating devices disposed, and a processing chamber 24 for performing vacuum processing on an object to be processed of the transfer unit 5. In this embodiment, the processing chamber 24 is a device for forming an MgO thin film or the like in a vacuum atmosphere or performing vacuum processing (such as, etching) in the vacuum atmosphere, and the chambers 21, 22, 24, and 29, other than the carry-in/take-out chamber 25, are evacuated to vacuum in advance.

Vacuum evacuation systems 75, 71, and 72, which are connected to the carry-in/take-out chamber 25 and the first and second degassing chambers 21 and 22, are connected to dry pumps 75a, 71a, and 72a and mechanical booster pumps 75b, 71b, and 72b, respectively, so that for vacuum evacuation from air pressure, the dry pumps 75a, 71a, and 72a are directly used for vacuum evacuation; and at pressures where the evacuation speeds of the dry pumps 75a, 71a, and 72a decrease, while the dry pumps 75a, 71a, and 72a evacuate to vacuum the backing pressure of the mechanical booster pumps 75b, 71b, and 72b, the mechanical booster pumps 75b, 71b, and 72b evacuate to vacuum the respective chambers 25, 21, and 22 (the transfer chamber 29 is connected to a high vacuum evacuation system which is not shown in the drawings and is thereby put in a vacuum atmosphere).

In the first and second degassing chambers 21 and 22, degassing is performed in sequentially at pressures of 1 Pa or higher, and after the amount of released gas has reduced, the transfer unit 5 is transferred into the processing chamber 24 through the transfer chamber 29.

The processing chamber 24 is connected to a vacuum evacuation system 73 which is composed of a turbomolecular pump, after the inside of the processing chamber 24 is evacuated to vacuum to 10⁻³ Pa, then the vacuum processing is started, after which the transfer unit 5 is taken out into the atmosphere from the carry-in/take-out chamber 25.

Since only the processing chamber 24 is provided with the turbomolecular pump, it is possible to put the processing chamber 24 in a high vacuum atmosphere with the vacuum evacuation systems of low cost.

FIG. 5(b) shows a vacuum processing apparatus 120 according to conventional technology, where a transfer chamber 129 is connected to a carry-in/take-out chamber 125, first and second degassing chambers 121 and 122, and a processing chamber 124. The chambers 121, 122, 124, and 129 other than the carry-in/take-out chamber 125 are evacuated to vacuum in advance. The processing chamber 124 and the first and second degassing chambers 121 and 122 are connected to respective vacuum evacuation systems 173, 171, and 172, each of which is composed of a turbomolecular pump, so as to be capable of vacuum evacuation to high vacuum.

A vacuum evacuation system connected to the carry-in/take-out chamber 125 includes a dry pump 175a, a mechanical booster pump 175b, and a turbomolecular pump 175c, wherein the carry-in/take-out chamber 125 is firstly evacuated to vacuum from air atmosphere by the dry pump 175a, the carry-in/take-out chamber 125 is then evacuated to vacuum by the mechanical booster pump 175b while evacuating to vacuum with the backing pressure evacuated by the dry pump 175a, until the pressure has been lowered to a pressure where the turbomolecular pump 175c is operable, after which vacuum evacuation by means of the turbomolecular pump 175c is started.

In such a state, the object to be transferred 5 is moved to the first degassing chamber 121, sequential degassing is performed in the first and second degassing chambers 121 and 122, while evacuating to vacuum by the evacuation systems 171 and 172, in order to lower the pressure in the processing chamber 124 to a pressure for vacuum processing.

The vacuum processing apparatus 20 of the present invention evacuated to vacuum from the air pressure to the pressure in which the vacuum processing could be started after heating and degassing, in the same time as the time that it took the vacuum processing apparatus 120 of the comparative example, that had turbomolecular pumps connected to the carry-in/take-out chamber 125, and to the first and second degassing chambers 121 and 122, as well as to the processing chamber 124. This means that the vacuum processing apparatus 20 of the present invention is lower in cost and easier to do maintenance.

1. A vacuum processing apparatus, comprising a degassing chamber that has a substrate heating mechanism and a processing chamber in which vacuum processing to a substrate is performed, the degassing chamber and the processing chamber being put in vacuum atmosphere, wherein an object to be processed, that has been heated and degassing processed inside the degassing chamber, is transferred into the processing chamber and vacuum processed inside the processing chamber,
wherein the evacuation speed of a degassing chamber vacuum evacuation device connected to the degassing chamber is set to be lower than the evacuation speed of a processing chamber vacuum evacuation device connected to the processing chamber.

2. The vacuum processing apparatus according to claim 1, wherein the degassing chamber vacuum evacuation device uses a vacuum pump that has an ultimate pressure which is higher than the ultimate pressure of the processing chamber vacuum evacuation device.

3. The vacuum processing apparatus according to claim 1, wherein an MgO deposition source is arranged in the processing chamber, and wherein MgO vapor of the MgO evaporation source is emitted to form an MgO thin film on a surface of the object to be processed.

4. The vacuum processing apparatus according to claim 1, comprising a plurality of the degassing chambers, the degassing chambers being connected in series, wherein, after the object to be processed is degassing processed in each of the degassing chambers, then moved to the processing chamber.

5. The vacuum processing apparatus according to claim 1,
wherein the degassing chamber vacuum evacuation device has an evacuation speed that brings the pressure inside the degassing chamber to a pressure atmosphere of at least 1 Pa and at most 100 Pa; and
wherein the processing chamber vacuum evacuation device has an evacuation speed that brings the pressure in the processing chamber to below 1 Pa.

6. A vacuum processing apparatus, comprising a degassing chamber that has a substrate heating mechanism; a buffer chamber that is connected to the degassing chamber; and a processing chamber that is connected to the buffer chamber, the degassing chamber, the buffer chamber, and the processing chamber being placed in a vacuum atmosphere, an object to be processed, that has been heated and degassing processed inside the degassing chamber, being transferred into the processing chamber through the buffer chamber and vacuum processed inside the processing chamber,
wherein the evacuation speed of a degassing chamber vacuum evacuation device connected to the degassing chamber is set to be lower than the evacuation speed of a buffer chamber vacuum evacuation device connected to the buffer chamber.

7. The vacuum processing apparatus according to claim 6, wherein the evacuation speed of the degassing chamber vacuum evacuation device is set to be lower than the evacuation speed of a processing chamber vacuum evacuation device connected to the processing chamber.

8. The vacuum processing apparatus according to claim 6, wherein the degassing chamber vacuum evacuation device uses a vacuum pump that has an ultimate pressure which is higher than the ultimate pressure of the buffer chamber vacuum evacuation device.

9. The vacuum processing apparatus according to claim 6, wherein an MgO deposition source is arranged in the processing chamber, and wherein an MgO vapor of the MgO deposition source is emitted to form an MgO thin film on a surface of the object to be processed.

10. The vacuum processing apparatus according to claim 6, further comprising a plurality of the degassing chambers, the degassing chambers being connected in series, and wherein, after the object to be processed is degassing processed in each of the degassing chambers, the object is then moved to the buffer chamber.

11. The vacuum processing apparatus according to claim 6,
wherein the degassing chamber vacuum evacuation device has an evacuation speed that brings the pressure in the degassing chamber to a pressure atmosphere of at least 1 Pa and at most 100 Pa, and
wherein the buffer chamber vacuum evacuation device has an evacuation speed that brings pressure inside the buffer chamber to below 1 Pa.

12. A vacuum processing method, comprising the steps of mounting an object to be processed onto a carrier to form a transfer unit, the transfer unit being carried from air atmosphere into a vacuum atmosphere, and after heating the transfer unit being heated and degassing processed inside a degassing chamber, then being transferred into a buffer chamber, after the pressure in the buffer chamber is lowered, then the buffer chamber is connected to a processing chamber, the transfer unit being transferred into the processing chamber, and the object to be processed in the transfer unit being vacuum processed, wherein pressure in the degassing chamber is brought into a pressure atmosphere of higher than or equal to 1 Pa and lower than or equal to 100 Pa, and pressure in the processing chamber is brought to below 1 Pa.

13. The vacuum processing method according to claim 12, wherein an MgO vapor is produced in the processing chamber to form an MgO thin film on a surface of the object to be processed.
